(19) United States
(12) Patent Application Publication
(10) Pub. No.: US 2019/0013369 A1
(43) Pub. Date: Jan. 10, 2019

(54) METHOD FOR FABRICATING FLEXIBLE OLED ARRAY SUBSTRATE, OLED DISPLAY PANEL

(71) Applicant: Wuhan China Star Optoelectronics Semiconductor Display Technology Co, Ltd., High-tech Development Zone, Wuhan, Hubei (CN)

(72) Inventors: Chenghao BU, Shenzhen, Guangdong (CN); Hong FANG, Shenzhen, Guangdong (US)

(73) Assignee: Wuhan China Star Optoelectronics Semiconductor Display Technology Co., Ltd., Wuhan, Hubei (CN)

(21) Appl. No.: 15/556,572

(22) PCT Filed: Aug. 17, 2017
(86) PCT No.: PCT/CN2017/097750

§ 371 Date: Sep. 7, 2017

(30) Foreign Application Priority Data
Jul. 6, 2017 (CN) 201710546604.X

(51) Int. Cl. H01L 27/32; H01L 27/12; H01L 51/52; H01L 51/00; H01L 51/56

(52) U.S. Cl. CPC H01L 27/3246; H01L 27/1214; H01L 51/56; H01L 51/0097; H01L 51/5203

(57) ABSTRACT

The present application discloses a method for fabricating a flexible OLED array substrate and an OLED display panel, wherein the method includes: providing a first substrate; forming a water-oxygen blocking layer on the first substrate; wherein the water-oxygen blocking layer is form by a graphene two-dimensional material; forming a TFT functional layer on the water-oxygen blocking layer, and forming a planarization layer, an electrode layer, and a pixel definition layer sequentially on the TFT functional layer. By the above-described method, the flexibility and the bending performance of the array substrate can be improved.

### FIELD OF THE INVENTION

The present application relates to a display technology field, and more particularly to a method for fabricating flexible OLED array substrate, OLED display panel.

### BACKGROUND OF THE INVENTION

With the Active-matrix organic light emitting diode, AMOLED display panel technology gets more and more mature in the industry, the demand of portable electronic devices for the display panel have become a demand for the flexible AMOLED display panel. The flexible OLED display panel with advantages of more compact, lower power consumption, can be bent into any shape to meet the market demand for wearable equipment and other.

However, the current flexible AMOLED display panel on the market is most only slightly bent at the edge, or is a curved panel with fixed radius of curvature, and is not have much difference with the conventional rigid OLED display, and did not reach the real meaning to be the foldable, can be curled and can be repeatedly bent into any shape.

### SUMMARY OF THE INVENTION

The technical problem that the present application mainly solves is to provide a method for fabricating a flexible OLED array substrate and an OLED display panel capable of improving the flexibility and bending performance of the array substrate. In order to solve the above-mentioned technical problems, a technical aspect of the present application is to provide a method for fabricating a flexible OLED array substrate, the method including: providing a first substrate; forming a water-oxygen blocking layer on the first substrate; wherein the water-oxygen blocking layer is form by a graphene-like two-dimensional material; forming a TFT functional layer on the water-oxygen blocking layer; and forming a planarization layer, an electrode layer and a pixel definition layer on the TFT functional layer.

In order to solve the above-mentioned technical problems, another technical aspect of the present application is to provide an OLED display array substrate, wherein the OLED array substrate includes a first substrate, a water-oxygen blocking layer, a TFT functional layer, a planarization layer, an electrode layer, and a pixel definition layer laminating arranged; wherein the water-oxygen blocking layer is formed by a graphene-like two-dimensional material.

In order to solve the above-mentioned technical problems, another technical aspect of the present application is to provide an OLED display panel, wherein the OLED panel is formed by the method for fabricating the technology approach described above or the OLED array substrate is the flexible OLED array substrate provided by the above technology approach.

The advantages of the present application is: comparing to the conventional technology, the method for fabricating a flexible OLED array substrate according to the present application includes: providing a first substrate; forming a water-oxygen blocking layer on the first substrate; wherein the water-oxygen blocking layer is form by a graphene-like two-dimensional material; forming a TFT functional layer on the water-oxygen blocking layer, and forming a planarization layer, an electrode layer, and a pixel definition layer sequentially on the TFT functional layer. By the above-described method, the flexibility and the bending performance of the array substrate can be improved.

### BRIEF DESCRIPTION OF THE DRAWINGS

In order to more clearly illustrate the embodiments of the present application or prior art, the following FIGS. will be described in the embodiments are briefly introduced. It is obvious that the drawings are merely some embodiments of the present application, those of ordinary skill in this field can obtain other FIGS. according to these FIGS. without paying the premise.

FIG. 1 is a schematic structural view of an embodiment of a flexible OLED array substrate according to the present application;

FIG. 2 is a schematic flow diagram of an embodiment of a method for fabricating the flexible OLED array substrate according to the present application;

FIG. 3 is a schematic flow diagram of S22 of an embodiment of the method for fabricating a flexible OLED array substrate according to the present application;

FIG. 4 is a schematic view of S222 in an embodiment of the method for fabricating a flexible OLED array substrate according to the present application;

FIGS. 5 to 9 are schematic views of the structure of S23 in an embodiment of the method for fabricating a flexible OLED array substrate according to the present application;

FIG. 10 is a schematic view of the structure of S24 in an embodiment of the method for fabricating a flexible OLED array substrate according to the present application; and

FIG. 11 is a schematic structural view of an embodiment of an OLED display panel according to the present application.

### DETAILED DESCRIPTION OF PREFERRED EMBODIMENTS

Embodiments of the present application are described in detail with the technical matters, structural features, achieved objects, and effects with reference to the accompanying drawings as follows. It is clear that the described embodiments are part of embodiments of the present application, but not all embodiments. Based on the embodiments of the present application, all other embodiments to those of ordinary skill in the premise of no creative efforts acquired should be considered within the scope of protection of the present application.

Specifically, the terminologies in the embodiments of the present application are merely for describing the purpose of the certain embodiment, but not to limit the invention.

Referring to FIG. 1, FIG. 1 is a schematic structural view of an embodiment of a flexible OLED array substrate according to the present application. The array substrate includes laminating arranged a first substrate 10, a water-oxygen blocking layer 11, a TFT functional layer, a planarization layer 19, an electrode layer 32 and a pixel definition layer 34.

Wherein, the water-oxygen blocking layer is form by graphene-like two-dimensional material. Specifically, the water-oxygen blocking layer is obtained by laminating a plurality layers of two-dimensional planar atomic layers, the two-dimensional planar atomic layer is hexagonal boron nitride (h-BN).

Wherein, the TFT functional layer includes a first insulating layer 12, an active layer 13, a second insulating layer 14, a gate electrode 15, a buffer layer 16, an organic filling layer 17, a source electrode 181 and a drain electrode 182 laminating arranged.

Wherein the active layer 13 specifically includes a source region and a drain region, the source electrode 181 is connected to the source region through the first through hole, and the drain electrode 182 is connected to the drain region through the second through hole.

Wherein the array substrate further includes a third through hole, the organic material of the organic filling layer 17 is filled in the third through hole, and the third through hole is as the stress releasing hole to reduce the bending stress when the panel is bent. It is to be noted that, the structure not shown in FIG. 1 can be seen in FIGS. 5 to 10 described later.

Hereinafter, a method for fabricating of the above-described array substrate will be described in detail with reference to an embodiment.

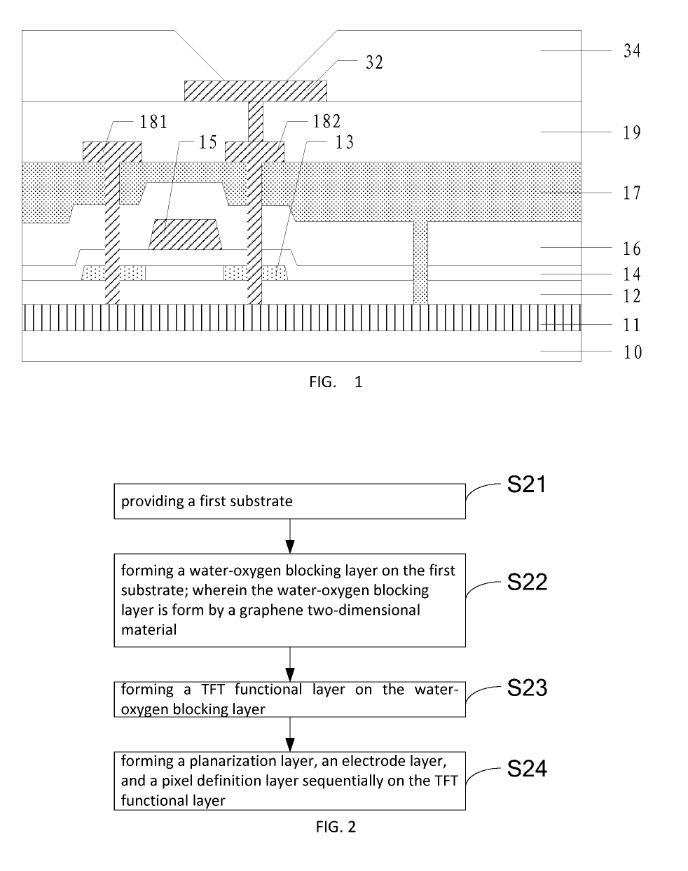

Referring to FIG. 2, FIG. 2 is a schematic flow diagram of an embodiment of a method for fabricating a flexible OLED array substrate according to the present application, the method includes:

S21: providing a first substrate.

Wherein, as a substrate in a flexible OLED, the first substrate can be form by a suitable flexible material, such as polyethylene terephthalate, PET or polyethylene naphthalate, PEN, but the present embodiment is not limited to this.

S22: forming a water-oxygen blocking layer on the first substrate; wherein the water-oxygen blocking layer is form by a graphene-like two-dimensional material.

The graphene-like two-dimensional material is a two-dimensional, 2D periodic honeycomb lattice structure that maintains a nanoscale scale, one or several atomic layer thicknesses in one dimension, and an infinitely carbon six-membered similar ring in a two-dimensional plane.

The use of this material, making the water-oxygen blocking layer has good chemical and thermal stability, excellent water and oxygen blocking properties, at the same time, because of its single atomic layer structure also makes the flexibility and bending of the material greatly increased.

Alternatively, the graphene two-dimensional material can be hexagonal boron nitride, h-BN, hexagonal boron nitride, h-BN and the like material having a monolithic layer of graphite six-membered ring structure, having good lubricity, electrical insulation, thermal conductivity and chemical resistance, with neutron absorption capacity. Having the chemical stability and is inertia to all molten metal chemical, molded products is for mechanical processing and have a high moisture resistance.

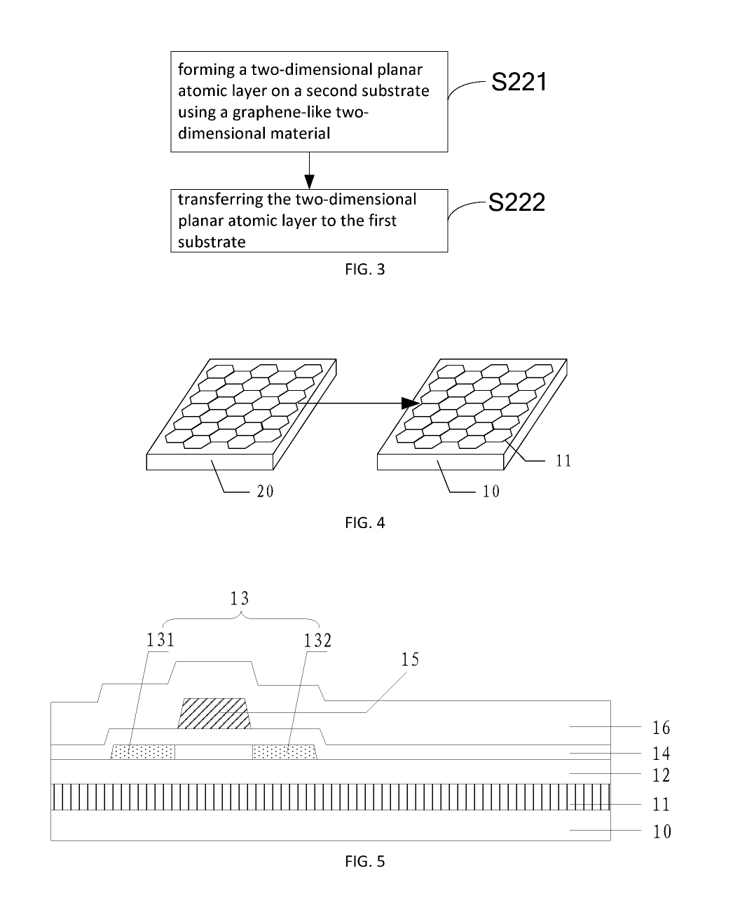

The fabrication of the water-oxygen blocking layer is described below with hexagonal boron nitride, h-BN as an example. Referring to FIG. 3, the step S22 can specifically include:

S221: forming a two-dimensional planar atomic layer on a second substrate using a graphene-like two-dimensional material.

S222: Transferring the two-dimensional planar atomic layer to the first substrate.

Repeating the above two steps of S221 and S222 to form a multilayer two-dimensional planar atomic layer on the first substrate to obtain a water-oxygen blocking layer.

Specifically, at the same time, in combination with FIG. 4, the two-dimensional atomic layer material hexagonal boron nitride, h-BN thin film can be grown on the second substrate 20 (for example, a copper foil can be used) by Chemical Vapor Deposition, CVD, and the single layer of hexagonal boron nitride, h-BN thin film is transferred from the second substrate 20 onto the first substrate 10 by a wet transfer technique, which is repeated several times to complete the transferring of the h-BN thin film, to form the h-BN thin film with several atomic layers, the h-BN thin film forms dense structure between the several atomic layers, and the close combination between the layers and layers can complement the defects during transferring process with each other, to achieve a well water-oxygen blocking effect, the material of h-BN is the two-dimensional single atomic material, the bending resistance performance is good, and is not easy to cracks or generating defects in the bending process.

S23: forming the TFT functional layer on the water-oxygen blocking layer.

The steps S23 will be described below with reference to FIGS. 5 to 9.

As shown in FIG. 5, a buffer layer 12 is formed on the water-oxygen blocking layer 11; an active layer 13 is formed on the buffer layer 12; and the active layer 13 is doped to form a source region 131 and the drain region 132 on the active layer 13; forming a first insulating layer 14 on the active layer 13; forming a first metal layer on the first insulating layer 14 and performing patterning process to the metal layer to form a gate electrode 15; and forming a second insulating layer 16 on the gate electrode.

Wherein, the buffer layer 12, the first insulating layer 14, and the second insulating layer 16 are all inorganic materials. Alternatively, SiOx, SiNx, or a mixture of SiOx and SiNx can be used, and no limitation is made here.

Wherein the fabrication of the active layer 13 can be specific as follows: first, depositing an amorphous silicon layer, i-Si and the amorphous silicon layer is converted into polycrystalline silicon, poly-Si by an excimer laser annealing, ELA process, then the polysilicon layer is patterned and performing ion-doped, to form an active layer 13 including the source region 131 and the drain region 132.

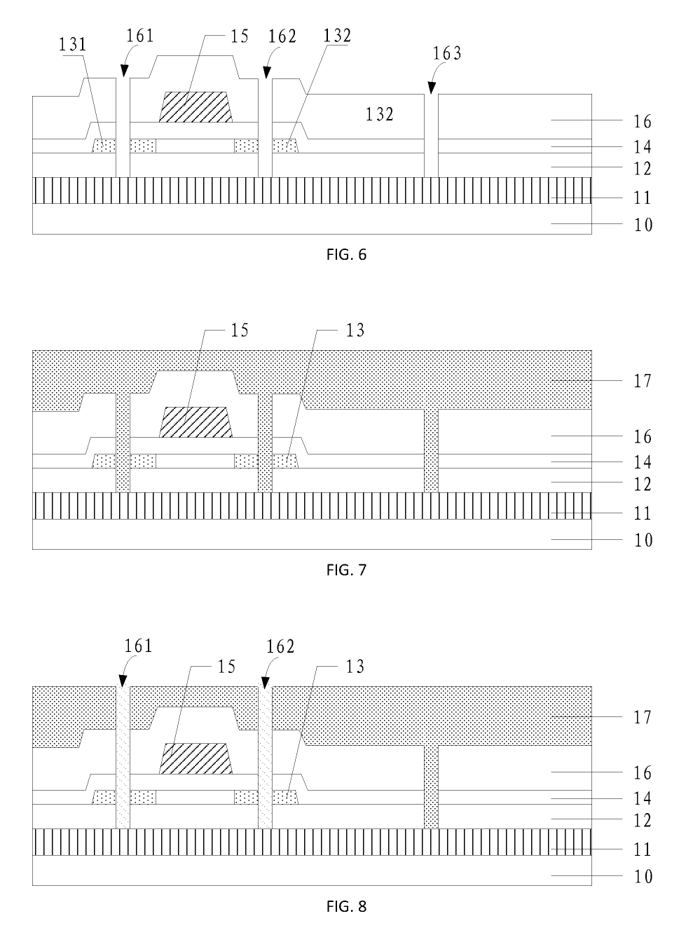

As shown in FIG. 6, the first through hole 161, the second through hole 162 and the third through hole 163 are formed by etch with one mask, wherein the bottom hole of the first through hole 161, the second through hole 162 and the third through hole 163 are all on the water-oxygen blocking layer 12, the first through hole 161 makes the source region 131 of the active layer 13 to be exposed, the second through hole 162 makes the drain region 132 of the active layer 13 to be exposed, and the third through hole 163 does not pass through the active layer 13 and the gate electrode 15. Wherein the first through hole 161 and the second through hole 162 do not pass through the gate electrode 15.

As shown in FIG. 7, an organic material is coated on the second insulating layer 16, and the organic material is filled in the first through hole 161, the second through hole 162, and the third through hole 163 to form the organic filling layer 17.

As shown in FIG. 8, the organic materials in the first through hole 161 and the second through hole 162 are removed, and the source region 131 and the drain region 132 are exposed again.

It will be appreciated that, during the removal of the organic material in the first through hole 161 and the second through hole 162, the organic material filled in the through hole can be completely removed, or it can be removed till only to the exposed source region 131 and the drain region 132, that is the organic material in the through hole in the buffer layer can be retained.

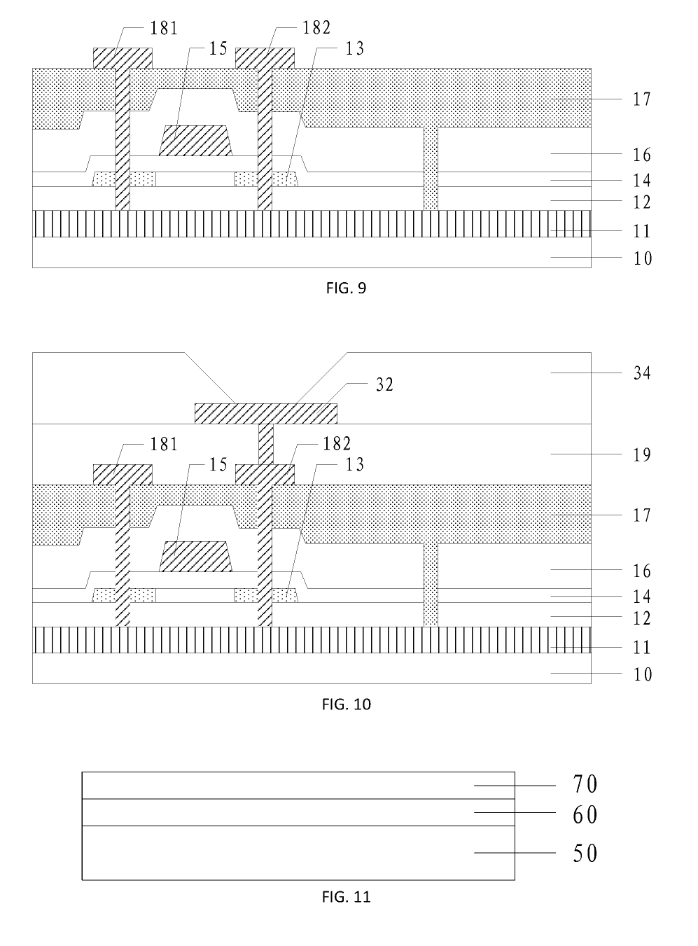

As shown in FIG. 9, a source electrode 181 and a drain electrode 182 are formed on the organic filling layer 17; wherein the source electrode 181 is connected to the source region 131 through the first through hole 161, and the drain electrode 182 is connected to the drain region 162 through the second through hole 162.

Specifically, when the source electrode 181 and the drain electrode 182 are fabricated, the second metal layer can be formed first on the organic filling layer 17, and the second metal layer can be patterned to form the source electrode 181 and the drain electrode 182.

It is to be noted that, in this step, the first through hole 161 can also be referred to as a source contact hole, the second through hole 162 can also be referred to as a drain contact hole, and the third through hole 163 can be referred to as a stress releasing hole, since the water-oxygen blocking layer 11 is a two-dimensional atomic layer of the h-BN material, with good bending resistance, so that the three through holes do not need to etch away the water-oxygen blocking layer 11, that is the bottom of the through holes is till the upper surface of the water-oxygen blocking layer, and the etching depths of the three through-holes can be set to be the same, so the same mask can be shared, reducing the process complexity.

It will be appreciated that, the organic material is retained in the third through hole 163 (stress releasing through hole), when the panel is bent, the bending can be occurred at the stress releasing hole, thereby reducing the stress between the thin films and increasing the performance of resistant to bending.

Alternatively, in the present embodiment, a stress releasing through hole can be used as an example. In other embodiments, the stress releasing through hole can be provided with a plurality of stress releasing through holes and the setting steps can be referred to the above-described, and is not repeated here.

S24: forming a planarization layer, an electrode layer, and a pixel definition layer sequentially on the TFT functional layer.

As shown in FIG. 10, the planarization layer 19 is formed on the organic filling layer 17; a fourth through hole (not shown) is formed on the planarization layer 19 so that one of the source electrode 181 or the drain electrode 182 is exposed; the third metal layer is formed on the planarization layer 19, and performing the pattern process to the third metal layer to form the electrode layer 32; wherein the electrode layer 32 is connected to the source electrode 181 or the drain electrode 182 through the third through hole; the pixel definition layer 34 is formed on the third metal layer.

It is to be understood that, the electrode layer 32 therein can be an anode or a cathode, which is not limited here.

It is to be understood that, in each of the above embodiments, the functional layer and the metal layer can be fabricated by using one or more than one method of physical vapor deposition or chemical vapor deposition, such as physical sputtering, spin coating, inkjet, slit coating or photolithography, etc., the present embodiment is not limited here.

In the above-described process, in one aspect, the water-oxygen blocking layer in the panel is form by a graphene-like two-dimensional material, and the flexibility and bending performance of the array substrate can be improved. On the other hand, a stress releasing hole is provided in the panel, when the bending of the panel is occurred at the stress releasing hole, the stress between the thin films can be reduced, and the bending resistance of the panel is increased.

Referring to FIG. 11, FIG. 11 is a schematic structural view of an embodiment of an OLED display panel according to the present application, the display panel includes an OLED array substrate 50, a light emitting device 60, and an upper substrate 70. Wherein, the OLED array substrate 50 is an array substrate provided as in the above embodiments, or is fabricated using a fabricating method as provided in the above-described embodiments.

It will be appreciated that, reference is made to the embodiments provided above, wherein the array substrate includes an electrode layer which can be serve as a first electrode layer. In addition, a second electrode layer is provided on the upper substrate, and the second electrode layer 70 is a cathode if the first electrode layer is an anode, and the second electrode layer 70 is an anode if the first electrode layer is a cathode.

Alternatively, when first electrode layer is an anode and the second electrode layer is a cathode, a hole injection layer and a hole transport layer can be included between the array substrate 50 and the light emitting device 60, and an electron injecting layer and an electron transporting layer can be included between the upper substrate 70 and the light emitting device 60.

Alternatively, when the first electrode layer is a cathode and the second electrode layer is an anode, the electron injecting layer and the electron transporting layer can be included between the array substrate 50 and the light emitting device 60, and the hole injection layer and the hole transport layer can be included between the upper substrate 70 and the light emitting device 60.

In addition, the OLED display panel can further include a cover plate, an inert gas filled, and the like, and will not be described again.

Above are embodiments of the present application, which does not limit the scope of the present application. Any modifications, equivalent replacements or improvements within the spirit and principles of the embodiment described above should be covered by the protected scope of the invention.

What is claimed is:

1. A method of fabricating a flexible OLED array substrate, comprising:
providing a first substrate;
forming a water-oxygen blocking layer on the first substrate; wherein the water-oxygen blocking layer is form by a graphene-like two-dimensional material;
forming a buffer layer, an active layer, a first insulating layer, a gate electrode, and a second insulating layer sequentially on the water-oxygen blocking layer;
forming a first through hole, a second through hole and a third through hole by etching with one mask; wherein, the bottom of the first through hole, the second through hole and the third through hole are on the water-oxygen blocking layer, and the first through hole makes a source region in the active layer exposed, the second through hole makes a drain region in the active layer exposed, and the third through hole does pass the active layer and the gate electrode;
coating an organic material on the second insulating layer and the organic material is filled in the first through hole, the second through hole and the third through hole to form an organic filling layer;
removing the organic material in the first through hole and the second through hole, re-exposing the source region and the drain region;
forming a source electrode and a drain electrode on the organic filling layer; wherein the source electrode is connected to the source region through the first through hole, and the drain electrode is connected to the drain region through the second through hole;
forming a planarization layer on the TFT functional layer;
forming a fourth through hole on the planarization layer, so that one of the source electrode or the drain electrode is exposed;
forming a third metal layer on the planarization layer and patterning the third metal layer to form an electrode layer; wherein the electrode layer is connected to the source electrode or the drain electrode through the third through hole; and
forming a pixel definition layer on the third metal layer.

2. The method according to claim 1, wherein the step of forming the water-oxygen blocking layer on the first substrate, comprising:
forming a layer of two-dimensional planar atomic layer on a second substrate by a graphene-like two-dimensional material;
Transferring the two-dimensional planar atomic layer onto the first substrate;
Repeating the above steps to form a multilayer two-dimensional planar atomic layer on the first substrate to obtain the water-oxygen blocking layer.

3. The method according to claim 2, wherein the graphene-like two-dimensional material is hexagonal boron nitride, h-BN.

4. The method according to claim 1, wherein the step of forming the buffer layer, the active layer, the first insulating layer, the gate electrode, and the second insulating layer sequentially on the water-oxygen blocking layer, comprising:
forming the buffer layer on the water-oxygen blocking layer;
forming the active layer on the buffer layer, and doping the active layer to form the source region and the drain region on the active layer;
forming the first insulating layer on the active layer;
forming a first metal layer on the first insulating layer and patterning the metal layer to form the gate electrode; and
forming the second insulating layer on the gate electrode.

5. The method according to claim 1, wherein the step of forming the source electrode and the drain electrode on the organic filling layer, comprising:
forming a second metal layer on the organic filling layer and patterning the second metal layer to form a source electrode and a drain electrode.

6. A method of fabricating a flexible OLED array substrate, comprising:
providing a first substrate;
forming a water-oxygen blocking layer on the first substrate; wherein the water-oxygen blocking layer is form by a graphene-like two-dimensional material;
forming a TFT functional layer on the water-oxygen blocking layer; and
forming a planarization layer, an electrode layer and a pixel definition layer on the TFT functional layer.

7. The method according to claim 6, wherein the step of forming the water-oxygen blocking layer on the first substrate, comprising:
forming a layer of two-dimensional planar atomic layer on a second substrate by a graphene-like two-dimensional material;
Transferring the two-dimensional planar atomic layer onto the first substrate;
Repeating the above steps to form a multilayer two-dimensional planar atomic layer on the first substrate to obtain the water-oxygen blocking layer.

8. The method according to claim 7, wherein the graphene-like two-dimensional material is hexagonal boron nitride, h-BN.

9. The method according to claim 6, wherein the step of forming the TFT functional layer on the water-oxygen blocking layer, comprising:
forming a buffer layer, an active layer, a first insulating layer, a gate electrode, and a second insulating layer sequentially on the water-oxygen blocking layer;
forming a first through hole, a second through hole and a third through hole by etching with one mask; wherein, the bottom of the first through hole, the second through hole and the third through hole are on the water-oxygen blocking layer, and the first through hole makes a source region in the active layer exposed, the second through hole makes a drain region in the active layer exposed, and the third through hole does pass the active layer and the gate electrode;
coating an organic material on the second insulating layer and the organic material is filled in the first through hole, the second through hole and the third through hole to form an organic filling layer;
removing the organic material in the first through hole and the second through hole, re-exposing the source region and the drain region; and
forming a source electrode and a drain electrode on the organic filling layer; wherein the source electrode is connected to the source region through the first through hole, and the drain electrode is connected to the drain region through the second through hole.

10. The method according to claim 9, wherein the step of forming the buffer layer, the active layer, the first insulating layer, the gate electrode, and the second insulating layer sequentially on the water-oxygen blocking layer, comprising:
forming the buffer layer on the water-oxygen blocking layer;
forming the active layer on the buffer layer, and doping the active layer to form the source region and the drain region on the active layer;
forming the first insulating layer on the active layer;
forming a first metal layer on the first insulating layer and patterning the metal layer to form the gate electrode; and
forming the second insulating layer on the gate electrode.

11. The method according to claim 9, wherein the step of forming the source electrode and The drain electrode on the organic filling layer, comprising:
forming a second metal layer on the organic filling layer and patterning the second metal layer to form a source electrode and a drain electrode.

12. The method according to claim 6, wherein the step of forming the planarization layer, an electrode layer and a pixel definition layer on the TFT functional layer, comprising:
forming the planarization layer on the TFT functional layer;
forming a fourth through hole on the planarization layer, so that one of the source electrode or the drain electrode is exposed;
forming a third metal layer on the planarization layer and patterning the third metal layer to form an electrode layer; wherein the electrode layer is connected to the source electrode or the drain electrode through the third through hole; and
forming a pixel definition layer on the third metal layer.

13. An OLED display panel, comprising: an OLED array substrate, wherein the OLED array substrate comprises a first substrate, a water-oxygen blocking layer, a TFT functional layer, a planarization layer, an electrode layer, and a pixel definition layer laminating arranged;
wherein the water-oxygen blocking layer is formed by a graphene-like two-dimensional material.

14. The OLED display panel according to claim 13, wherein the water-oxygen blocking layer is obtained by laminating multilayers of a two-dimensional planar atomic layer, and the two-dimensional planar atomic layer is hexagonal boron nitride, h-BN.

15. The OLED display panel according to claim 13, wherein the graphene-like two-dimensional material is hexagonal boron nitride, h-BN.

16. The OLED display panel according to claim 13, wherein the TFT functional layer comprises a buffer layer, an active layer, a first insulating layer, a gate electrode, a second insulating layer, an organic filling layer, a source electrode and a drain electrode sequentially formed on the water-oxygen blocking layer.
